(19) United States
(12) Patent Application Publication
(10) Pub. No.: US 2026/0314404 A1
(43) Pub. Date: Oct. 8, 2026

(54) SEMICONDUCTOR PACKAGE

(71) Applicant: SAMSUNG ELECTRONICS CO., LTD., Suwon-si (KR)

(72) Inventors: Geongu Ji, Suwon-si (KR); Myungsung Kang, Suwon-si (KR)

(73) Assignee: SAMSUNG ELECTRONICS CO., LTD., Suwon-si (KR)

(21) Appl. No.: 19/641,128

(22) Filed: Apr. 7, 2026

(30) Foreign Application Priority Data
Apr. 7, 2025 (KR) 10-2025-0044935

(51) Int. Cl. H10W 40/20; H10W 72/00; H10W 74/10

(52) U.S. Cl. CPC H10W 40/242; H10W 40/235; H10W 72/823; H10W 74/111; H10W 74/131

(57) ABSTRACT

A semiconductor package includes a first redistribution structure, a first semiconductor chip on the first redistribution structure, a conductive pillar on the first redistribution structure and spaced from the first semiconductor chip in a horizontal direction, a molding member on the first redistribution structure and around the first semiconductor chip and the conductive pillar, a second redistribution structure on the molding member, a second semiconductor chip on the second redistribution structure, a first thermally conductive adhesive layer on the second redistribution structure, a second thermally conductive adhesive layer on an upper surface of the second semiconductor chip, and a heat transfer block on the second redistribution structure and including a protrusion portion in contact with the second thermally conductive adhesive layer, and a body portion in contact with the first thermally conductive adhesive layer.

### CROSS-REFERENCE TO RELATED APPLICATION

This application is based on and claims priority under 35 U.S.C. §119 to Korean Patent Application No. 10-2025-0044935, filed on Apr. 7, 2025, in the Korean Intellectual Property Office, the disclosure of which is incorporated by reference herein in its entirety.

### BACKGROUND

The disclosure relates to a semiconductor package, and more particularly, to a semiconductor package including a heat transfer block.

Recently, the demand for portable devices is increasing rapidly in the electronic product market, and as a result, miniaturization and weight reduction of electronic components mounted on these electronic products are continuously required. For miniaturization and weight reduction of electronic components, semiconductor packages mounted on the electronic components are required to process high-capacity data while their volume is reduced. With the miniaturization and weight reduction of semiconductor packages, technology that dissipates heat generated from semiconductor chips and technology that prevents distortion inside semiconductor packages are required.

### SUMMARY

One or more embodiments provide a semiconductor package which may have improved structural reliability and thermal characteristics.

In addition, the problems to be solved by the disclosure are not limited to the above-mentioned problems, and other problems may be clearly understood by those skilled in the art from the description below.

According to an aspect of the disclosure, there is provided a semiconductor package including: a first redistribution structure; a first semiconductor chip on the first redistribution structure; at least one conductive pillar on the first redistribution structure and spaced apart from the first semiconductor chip in a horizontal direction; a molding member on the first redistribution structure and around the first semiconductor chip and the at least one conductive pillar; a second redistribution structure on the molding member; a second semiconductor chip on the second redistribution structure; a first thermally conductive adhesive layer on the second redistribution structure; a second thermally conductive adhesive layer on an upper surface of the second semiconductor chip; and a heat transfer block on the second redistribution structure, the heat transfer block including: a protrusion portion in contact with the second thermally conductive adhesive layer, and a body portion in contact with the first thermally conductive adhesive layer.

According to an aspect of the disclosure, there is provided a semiconductor package including: a first redistribution structure; a first semiconductor chip on the first redistribution structure; a conductive pillar on the first redistribution structure and spaced apart from the first semiconductor chip in a horizontal direction; a molding member on the first redistribution structure and around the first semiconductor chip and the conductive pillar; a second redistribution structure on the molding member; a second semiconductor chip on the second redistribution structure; a first thermally conductive adhesive layer on the second redistribution structure; a second thermally conductive adhesive layer on an upper surface of the second semiconductor chip; a heat transfer block on the second redistribution structure, the heat transfer block including: a protrusion portion in contact with an upper surface of the second thermally conductive adhesive layer, and a body portion in contact with an upper surface of the first thermally conductive adhesive layer, and spaced apart from the second semiconductor chip in the horizontal direction; a third thermally conductive adhesive layer on an upper surface of the heat transfer block; and a heat dissipation member on the third thermally conductive adhesive layer.

According to an aspect of the disclosure, there is provided a semiconductor package including: a package substrate; a first redistribution structure including a first redistribution pattern and a first redistribution insulating layer on the package substrate; a first semiconductor chip on the first redistribution structure and having a center spaced apart from a center of the first redistribution structure in a horizontal direction; a plurality of conductive pillars on the first redistribution structure and spaced apart from the first semiconductor chip in the horizontal direction; a molding member on the first redistribution structure and around the first semiconductor chip and the plurality of conductive pillars; a second redistribution structure on the molding member and including a second redistribution pattern and a second redistribution insulating layer; a second semiconductor chip on the second redistribution structure and overlapping at least one of the plurality of conductive pillars in a vertical direction; a first thermally conductive adhesive layer on the second redistribution structure; a second thermally conductive adhesive layer on an upper surface of the second semiconductor chip; a heat transfer block on the second redistribution structure, in contact with an upper surface of the second thermally conductive adhesive layer and an upper surface of the first thermally conductive adhesive layer, and spaced apart from the second semiconductor chip in the horizontal direction; a third thermally conductive adhesive layer on an upper surface of the heat transfer block; and a heat dissipation member on the third thermally conductive adhesive layer, wherein a thermal conductivity of the first thermally conductive adhesive layer is greater than a thermal conductivity of the second thermally conductive adhesive layer, an adhesion of the second thermally conductive adhesive layer is greater than an adhesion of the first thermally conductive adhesive layer, the third thermally conductive adhesive layer includes a sheet type, a thickness of the first thermally conductive adhesive layer in the vertical direction is within a range of about 45 μm to about 55 μm, and a thickness of the second thermally conductive adhesive layer in the vertical direction is within a range of about 50 μm to about 100 μm.

According to an aspect of the disclosure, there is provided a method of manufacturing a semiconductor package including forming a first redistribution structure on a first carrier substrate, forming a plurality of conductive pillars on the first redistribution structure, mounting a plurality of first semiconductor chips on the first redistribution structure, forming a molding member surrounding the plurality of conductive pillars and the plurality of first semiconductor chips, forming a second redistribution structure on the molding member, cutting the first redistribution structure, the molding member, and the second redistribution structure along a scribe lane and separating the same into an individual structure, mounting a second semiconductor chip on an upper surface of the second redistribution structure of the separated individual structure, forming a first thermally conductive adhesive layer on the upper surface of the second redistribution structure and forming a second thermally conductive adhesive layer on an upper surface of the second semiconductor chip, forming a heat transfer block in contact with an upper surface of each of the first thermally conductive adhesive layer and the second thermally conductive adhesive layer and including a protrusion portion and a body portion, forming a third thermally conductive adhesive layer on an upper surface of the heat transfer block, and forming a heat dissipation member on an upper surface of the third thermally conductive adhesive layer.

In one or more embodiments, the method may include, between the forming of the second redistribution structure on the molding member and the cutting of the first redistribution structure, the molding member, and the second redistribution structure along the scribe lane and separating the same into the individual structure, removing the first carrier substrate, attaching a second carrier substrate on the upper surface of the second redistribution structure, and inverting the second carrier substrate in a vertical direction, forming a substrate connection bump and a passive element component on a lower surface of the first redistribution structure, and removing the second carrier substrate and attaching a saw tape to the lower surface of the first redistribution structure.

In one or more embodiments, the second semiconductor chip may be mounted on the upper surface of the second redistribution structure through a chip connection bump and an underfill material layer.

In one or more embodiments, the first thermally conductive adhesive layer may be in contact with the underfill material layer in a lateral direction.

In one or more embodiments, the heat transfer block may have a shape surrounding the upper surface and side surfaces of the second semiconductor chip.

In one or more embodiments, an adhesive member may be located on three side surfaces of the second semiconductor chip, and may adhere an inner surface of the heat transfer block to the three side surfaces of the second semiconductor chip.

In one or more embodiments, a thermal conductivity of the first thermally conductive adhesive layer may be greater than a thermal conductivity of the second thermally conductive adhesive layer, and an adhesion of the second thermally conductive adhesive layer may be higher than an adhesion of the first thermally conductive adhesive layer.

In one or more embodiments, a thickness of the first thermally conductive adhesive layer in the vertical direction may be within the range of about 45 μm to about 55 μm, and a thickness of the second thermally conductive adhesive layer in the vertical direction may be within the range of about 50 μm to about 100 μm.

In one or more embodiments, a dam surrounding the third thermally conductive adhesive layer may be located on the upper surface of the heat transfer block.

In one or more embodiments, the dam may include a film having adhesive properties.

### BRIEF DESCRIPTION OF DRAWINGS

The above and/or other aspects will be more clearly understood from the following detailed description taken in conjunction with the accompanying drawings, in which:

FIG. 1 is a cross-sectional view illustrating a semiconductor package according to an embodiment;

FIG. 2 is a cross-sectional view illustrating a semiconductor package according to an embodiment;

FIG. 3 is a plan view taken along line A1-A1’ of FIG. 2 according to an embodiment;

FIG. 4 is a cross-sectional view illustrating a semiconductor package according to an embodiment;

FIG. 5A is a cross-sectional view illustrating a semiconductor package according to an embodiment;

FIG. 5B is a plan view taken along line B1-B1’ of FIG. 5A;

FIG. 6 is a cross-sectional view illustrating a semiconductor package according to an embodiment;

FIG. 7 is a cross-sectional view illustrating a semiconductor package according to an embodiment; and

FIGS. 8 to 18 are cross-sectional views illustrating a method of manufacturing a semiconductor package.

### DETAILED DESCRIPTION

Hereinafter, example embodiments of the disclosure will be described in detail with reference to the accompanying drawings. The same reference numerals may be used for the same components in the drawings, and redundant descriptions thereof are omitted.

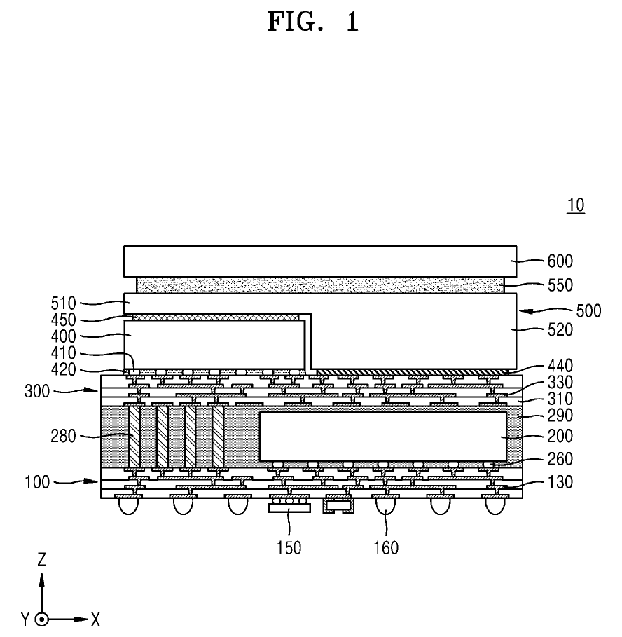

FIG. 1 is a cross-sectional view illustrating a semiconductor package according to an embodiment.

Referring to FIG. 1, a semiconductor package 10 according to the disclosure may include a first redistribution structure 100, a first semiconductor chip 200, a conductive pillar 280, a molding member 290, a second redistribution structure 300, a second semiconductor chip 400, a first thermally conductive adhesive layer 440, a second thermally conductive adhesive layer 450, a heat transfer block 500, a third thermally conductive adhesive layer 550, and a heat dissipation member 600.

The first redistribution structure 100 may include an upper surface and a lower surface opposite each other, and at least one of the upper surface or the lower surface may be a flat surface. The first redistribution structure 100 may be disposed in a lower portion of the first semiconductor chip 200 and may electrically connect the first semiconductor chip 200 to a substrate connection bump 160. A passive element component 150 may be located on the lower surface of the first redistribution structure 100. For example, the passive element component 150 may include a capacitor such as a multi-layer ceramic capacitor (MLCC) or a low inductance chip capacitor (LICC), an inductor, and a bead (e.g., a ferrite bead). The first redistribution structure 100 may include a first redistribution insulating layer 110 and a first redistribution pattern 130. The first redistribution insulating layer 110 may be provided as a plurality of insulating layers stacked in one direction, and the first redistribution pattern 130 may include a plurality of patterns formed in the stacked insulating layers.

In the following drawings, a direction in which a plurality of insulating layers are stacked may be understood as a Z-axis direction, and an X-axis direction and a Y-axis direction may be perpendicular to each other in a plane having the Z-axis direction as a normal vector. In the same sense, the X-axis direction and the Y-axis direction indicate directions parallel to the surface of the upper surface or the lower surface of the first redistribution structure 100, and the X-axis direction and the Y-axis direction may be perpendicular to each other. In addition, in the following drawings, a first horizontal direction, a second horizontal direction, and a vertical direction may be understood as follows: The first horizontal direction may be understood as the X-axis direction, the second horizontal direction may be understood as the Y-axis direction, and the vertical direction may be understood as the Z-axis direction.

The first redistribution pattern 130 may be electrically connected to each of the first semiconductor chip 200, the conductive pillar 280, the substrate connection bump 160, and the passive element component 150. The first redistribution pattern 130 may include a first redistribution via and a first redistribution line. The first redistribution line of the first redistribution pattern 130 may have a shape extending in the first horizontal X-axis direction in the first redistribution insulating layer 110. According to one or more embodiments, the first redistribution line of the first redistribution pattern 130 may be provided to each of the plurality of first redistribution insulating layers 110 stacked in the vertical Z-axis direction. The first redistribution via of the first redistribution pattern 130 may extend in the vertical Z-axis direction and penetrate the first redistribution insulating layer 110 in the vertical Z-axis direction. The first redistribution via of the first redistribution pattern 130 may electrically connect first redistribution lines of the first redistribution pattern 130 formed respectively in the first redistribution insulating layers 110, which may be different from each other.

In one or more embodiments, the first redistribution via of the first redistribution pattern 130 may have a tapered shape in which its horizontal width increases and extends from a lower side to an upper side. For example, the horizontal width of the first redistribution via of the first redistribution pattern 130 may increase toward the first semiconductor chip 200. In one or more embodiments, the first redistribution via of the first redistribution pattern 130 may have a tapered shape in which its horizontal width increases as a level according to the vertical Z-axis direction decreases.

According to one or more embodiments, the first redistribution structure 100 may be a redistribution structure manufactured through a redistribution process. For example, the first redistribution structure 100 may be formed by using a semi-additive process (SAP) method, a dual damascene process, a tenting process, etc. In this regard, the first redistribution insulating layer 110 may include, for example, a photo imageable dielectric (PID) or photosensitive polyimide (PSPI), and the first redistribution pattern 130 may be, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy of metals, but is not limited thereto. In some embodiments, the first redistribution pattern 130 may be formed by stacking a metal or an alloy of metals on a seed layer including copper, titanium, titanium nitride, or titanium tungsten. According to one or more embodiments, the first redistribution line of the first redistribution pattern 130 may be formed together with the first redistribution via of the first redistribution pattern 130 and be integrated therewith.

The substrate connection bump 160 may be located in a lower portion of the first redistribution structure 100. According to one or more embodiments, the substrate connection bump 160 may be electrically connected to a package substrate. The substrate connection bump 160 may be electrically connected to the first redistribution pattern 130. The substrate connection bump 160 may receive an electrical signal transmitted from the first semiconductor chip 200 and the conductive pillar 280 through the first redistribution pattern 130, and may transmit the electrical signal to the package substrate. The substrate connection bump 160 may include a conductive material, for example, at least one of solder, tin (Sn), silver (Ag), copper (Cu), or aluminum (Al).

The first semiconductor chip 200 may be mounted on the upper surface of the first redistribution structure 100. The first semiconductor chip 200 may be electrically connected to the first redistribution pattern 130. According to embodiments, the first semiconductor chip 200 may be mounted on the first redistribution structure 100 in a flip-chip manner through a chip connection bump 260 such as a microbump. In some one or more embodiments, the first semiconductor chip 200 may be mounted on the first redistribution structure 100 in a flip-chip manner through a molded underfill (MUF) process. That is, the molding member 290 may be directly filled with a gap between the first semiconductor chip 200 and the first redistribution structure 100 while surrounding the chip connection bump 260. However, in some embodiments, an underfill material layer surrounding the chip connection bump 260 may be disposed between the first semiconductor chip 200 and the first redistribution structure 100.

According to one or more embodiments, the first semiconductor chip 200 may be located on one side of the first redistribution structure 100. That is, the center of the first redistribution structure 100 and the center of the first semiconductor chip 200 may be spaced apart from each other in the first horizontal X-axis direction.

The first semiconductor chip 200 may include a logic chip. For example, the logic chip may be a central processing unit (CPU), a graphics processing unit (GPU), a microprocessor such as an application processor (AP), an analog device, or a digital signal processor.

The conductive pillar 280 may be located on the first redistribution structure 100. The conductive pillar 280 may be located on the first redistribution structure 100 and be spaced apart from the first semiconductor chip 200 in the first horizontal X-axis direction. A plurality of conductive pillars 280 may be provided. In some embodiments, the plurality of conductive pillars 280 may be located only on one side of the first semiconductor chip 200. That is, the plurality of conductive pillars 280 may be located only on the left side of the first semiconductor chip 200 in a negative X-axis (i.e., -X) direction and not on the right side of the first semiconductor chip 200 in a positive X-axis (i.e., +X) direction with respect to FIG. 1.

The conductive pillar 280 may electrically connect a second redistribution pattern 330 of the second redistribution structure 300 to the first redistribution pattern 130 of the first redistribution structure 100. The conductive pillar 280 may extend in the vertical Z-axis direction through the molding member 290. The conductive pillar 280 may be, for example, a through-mold via or a conductive post. The conductive pillar 280 may include, for example, copper (Cu).

The molding member 290 may surround the first semiconductor chip 200 and the conductive pillar 280 on the first redistribution structure 100. The molding member 290 may include a thermosetting resin such as an epoxy resin, a thermoplastic resin such as polyimide, or a resin including a reinforcing material such as an inorganic filler, specifically, an Ajinomoto build-up film (ABF), FR-4, BT, etc., but is not limited thereto, and the molding member 290 may include a molding material such as epoxy molding compounds (EMC) or a photosensitive material such as a photoimagable encapsulant (PIE). In one or more embodiments, a part of the molding member 290 may include an insulating material such as a silicon oxide layer, a silicon nitride layer, or a silicon oxynitride layer.

The second redistribution structure 300 may be located on an upper surface of the molding member 290. The second redistribution structure 300 may include a second redistribution insulating layer 310 and the second redistribution pattern 330. The second redistribution insulating layer 310 may be provided as a plurality of insulating layers stacked in the vertical Z-axis direction, and the second redistribution pattern 330 may include a plurality of patterns formed in the stacked insulating layers.

The second redistribution pattern 330 may be electrically connected to each of the second semiconductor chip 400 and the conductive pillar 280. The second redistribution pattern 330 may include a second redistribution via and a second redistribution pattern.

The second semiconductor chip 400 may be located on the second redistribution structure 300. The second semiconductor chip 400 may be located on the second redistribution structure 300 and be spaced apart from a body portion 520 of the heat transfer block 500 in the first horizontal X-axis direction. The second semiconductor chip 400 may be electrically connected to the second redistribution pattern 330. According to one or more embodiments, the second semiconductor chip 400 may be mounted on the second redistribution structure 300 in a flip chip manner through a chip connection bump 410 such as a microbump. According to one or more embodiments, an underfill material layer 420 surrounding the chip connection bump 410 may be disposed between the second semiconductor chip 400 and the second redistribution structure 300. The second semiconductor chip 400 may include a memory chip. For example, the memory chip may be a volatile memory chip such as dynamic random access memory (DRAM) or static random access memory (SRAM), or a nonvolatile memory chip such as phase-change random access memory (PRAM), magnetoactive random access memory (MRAM), ferroelectric random access memory (FeRAM), or resistive random access memory (RRAM). In addition, according to one or more embodiments, the memory chip may be a high bandwidth memory (HBM) in which a plurality of memory chips are stacked in the vertical Z-axis direction or a wire bonding memory package.

According to one or more embodiments, the second semiconductor chip 400 may overlap at least one of the plurality of conductive pillars 280 in the vertical Z-axis direction.

In one or more embodiments, the second semiconductor chip 400 may be a memory chip sealed by a molding material. Therefore, side surfaces of the second semiconductor chip 400 may include a molding material.

The heat transfer block 500 may be located on the second redistribution structure 300. The heat transfer block 500 may be provided on the second redistribution structure 300 and be spaced apart from the second semiconductor chip 400 in the first horizontal X-axis direction and the vertical Z-axis direction.

The heat transfer block 500 may be fixed on the second redistribution structure 300 by the first thermally conductive adhesive layer 440. A lower surface of the heat transfer block 500 may be in contact with the first thermally conductive adhesive layer 440.

The heat transfer block 500 may provide a path for transferring heat generated from the first semiconductor chip 200 to the heat dissipation member 600. Accordingly, the heat transfer block 500 may be located close to or adjacent to the second semiconductor chip 400. The heat transfer block 500 may include the body portion 520 and a protrusion portion 510. The body portion 520 may overlap the first semiconductor chip 200 in the vertical Z-axis direction. With respect to FIG. 1, the body portion 520 may be located on the right side of the second semiconductor chip 400 on the second redistribution structure 300. Accordingly, heat generated from the first semiconductor chip 200 may be transferred to the heat dissipation member 600 through the body portion 520.

The protrusion portion 510 may extend from one or more side surfaces of the body portion 520 toward an upper portion of the second semiconductor chip 400 in the first horizontal X-axis direction. An upper surface and a lower surface of the protrusion portion 510 may be flat. The protrusion portion 510 may be fixed to an upper surface of the second semiconductor chip 400 through the second thermally conductive adhesive layer 450. The protrusion portion 510 may include a material resistant to distortion. The protrusion portion 510 may hold the upper surface of the second semiconductor chip 400 through the second thermally conductive adhesive layer 450. Accordingly, when heat is applied during the manufacturing process of the semiconductor package 10, even though distortion occurs in the second semiconductor chip 400 due to a difference in a thermal expansion coefficient of the second semiconductor chip 400 and a thermal expansion coefficient of the heat transfer block 500, the protrusion portion 510 and the second semiconductor chip 400 are fixed, thereby preventing the second semiconductor chip 400 from being distorted due to the difference in the thermal expansion coefficients.

The first thermally conductive adhesive layer 440 may be disposed between a lower surface of the body portion 520 of the heat transfer block 500 and the upper surface of the second redistribution structure 300. In one or more embodiments, the footprint of the first thermally conductive adhesive layer 440 may be smaller than the footprint of the lower surface of the body portion 520. In one or more embodiments, the footprint of the first thermally conductive adhesive layer 440 may be larger than the footprint of the lower surface of the body portion 520.

According to embodiments, the first thermally conductive adhesive layer 440 may include an insulating material, or may include a material including an insulating material and capable of maintaining electrical insulation. The first thermally conductive adhesive layer 440 may include a resin and a filler. According to embodiments, the first thermally conductive adhesive layer 440 may include silicone as the resin, and may include aluminum as the filler. Accordingly, the first thermally conductive adhesive layer 440 may easily transfer heat generated from the first semiconductor chip 200 to the heat dissipation member 600.

In some embodiments, a thickness of the first thermally conductive adhesive layer 440 in the vertical Z-axis direction may range from about 45 μm to about 55 μm.

The second thermally conductive adhesive layer 450 may be disposed between the lower surface of the protrusion portion 510 of the heat transfer block 500 and the upper surface of the second semiconductor chip 400. According to embodiments, the second thermally conductive adhesive layer 450 may include an insulating material, or may include a material including an insulating material and capable of maintaining electrical insulation. The second thermally conductive adhesive layer 450 may include a resin and a filler. According to embodiments, the second thermally conductive adhesive layer 450 may include epoxy as the resin, and may include silver (Ag) as the filler. In some embodiments, a thickness of the second thermally conductive adhesive layer 450 in the vertical Z-axis direction may range from about 50 μm to about 100 μm.

The first thermally conductive adhesive layer 440 may easily transfer heat generated from the first semiconductor chip 200 to the heat dissipation member 600 while attaching the heat transfer block 500 to the second redistribution structure 300. On the other hand, the second thermally conductive adhesive layer 450 may easily transfer heat generated from the second semiconductor chip 400 to the heat dissipation member 600, and simultaneously prevent distortion of the second semiconductor chip 400 by combining the second semiconductor chip 400 with the protrusion portion 510 of the heat transfer block 500.

Therefore, a thermal conductivity of the first thermally conductive adhesive layer 440 may be greater than a thermal conductivity of the second thermally conductive adhesive layer 450, and an adhesion of the first thermally conductive adhesive layer 440 may be less than an adhesion of the second thermally conductive adhesive layer 450.

That is, in terms of heat conduction, the first thermally conductive adhesive layer 440 may include a material having higher (i.e., greater or larger) thermal conductivity than the second thermally conductive adhesive layer 450, and in terms of adhesion, the second thermally conductive adhesive layer 450 may include a material having higher (i.e., greater or stronger) adhesion than the first thermally conductive adhesive layer 440.

According to one or more embodiments, a content ratio of the resin constituting the first thermally conductive adhesive layer 440 may be less than a content ratio of the resin constituting the second thermally conductive adhesive layer 450. Here, the content ratio of the resin may be understood as a weight content ratio of the resin. Accordingly, the adhesion of the second thermally conductive adhesive layer 450 may be stronger than the adhesion of the first thermally conductive adhesive layer 440.

The third thermally conductive adhesive layer 550 may be located on an upper surface of the heat transfer block 500. The third thermally conductive adhesive layer 550 may be located between the heat transfer block 500 and the heat dissipation member 600. The third thermally conductive adhesive layer 550 may be deposited or applied evenly on the upper surface of the heat transfer block 500. The third thermally conductive adhesive layer 550 may include an insulating material, or may include a material including an insulating material capable of maintaining electrical insulation. The third thermally conductive adhesive layer 550 may include, for example, an insulating base layer such as an epoxy resin, and/or a heat dissipation filler included in the insulating base layer. For example, the third thermally conductive adhesive layer 550 may include mineral oil, grease, gap filler putty, phase change gel, phase change material pads, or powder filled epoxy.

According to one or more embodiments, the third thermally conductive adhesive layer 550 may be provided in the form of a sheet. According to one or more embodiments, the third thermally conductive adhesive layer 550 may be provided as a solid material in the form of the sheet and then converted into a liquid material by heat to be in close contact with surfaces of the heat transfer block 500 and the heat dissipation member 600. In one or more embodiments, the third thermally conductive adhesive layer 550 may be provided in the form of a graphite sheet.

According to one or more embodiments, each of the first thermally conductive adhesive layer 440, the second thermally conductive adhesive layer 450, and the third thermally conductive adhesive layer 550 may be understood as a thermal interfacial material (TIM).

The heat dissipation member 600 may be located on an upper surface of the third thermally conductive adhesive layer 550. The heat dissipation member 600 may include a heat slug or a heat sink. In one or more embodiments, the heat dissipation member 600 may be a flat plate or a three-dimensional plate including a metal material. The heat dissipation member 600 may include any one or more materials selected from the group consisting of copper, copper alloy, aluminum, aluminum alloy, steel, stainless steel, and a combination thereof.

In the related art, when heat is applied in the manufacturing process with the second semiconductor chip 400 located on one side of the upper surface of the second redistribution structure 300 and the heat transfer block 500 located on the other side, distortion of the second semiconductor chip 400 frequently occurs due to the difference in the thermal expansion coefficient between the second semiconductor chip 400 and the heat transfer block 500.

In addition, as described below, in the manufacturing process, the first thermally conductive adhesive layer 440 may be first formed on the second redistribution structure 300, the heat transfer block 500 may be attached, and then the second semiconductor chip 400 may be mounted, which may make it difficult to form a large footprint of the first thermally conductive adhesive layer 440. When the large footprint of the first thermally conductive adhesive layer 440 is formed, an upper pad of the second redistribution structure 300 that may need to connect to the second semiconductor chip 400 may be invaded by the first thermally conductive adhesive layer 440, which may cause a connection failure.

However, in the semiconductor package 10 according to one or more embodiments of the disclosure, the heat transfer block 500 may include the protrusion portion 510, and the protrusion portion 510 may be located on the upper portion of the second semiconductor chip 400. In addition, the protrusion portion 510 may be attached to the upper surface of the second semiconductor chip 400 through the second thermally conductive adhesive layer 450 having strong adhesion. Accordingly, even though heat is generated during the manufacturing process, the second semiconductor chip 400 may be prevented from being distorted due to the difference in the thermal expansion coefficient.

In addition, the semiconductor package 10 according to one or more embodiments of the disclosure may first mount the second semiconductor chip 400 after forming the second redistribution structure 300, as described below. Then, the heat transfer block 500 is mounted on the second redistribution structure 300 through the first thermally conductive adhesive layer 440, and thus the connection failure of the second semiconductor chip 400 may be prevented even though the footprint of the first thermally conductive adhesive layer 440 may be increased.

Furthermore, because the protrusion portion 510 of the heat transfer block 500 is located on the upper surface of the second semiconductor chip 400 on the upper surface of the second redistribution structure 300, the difference in the thermal expansion coefficient between the left and right sides of the semiconductor package 10 with respect to the center the second redistribution structure 300 may be less than when the protrusion portion 510 is not formed.

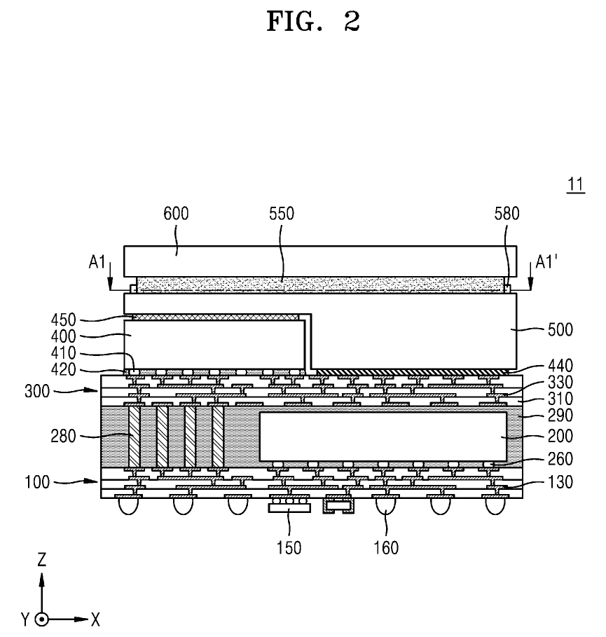

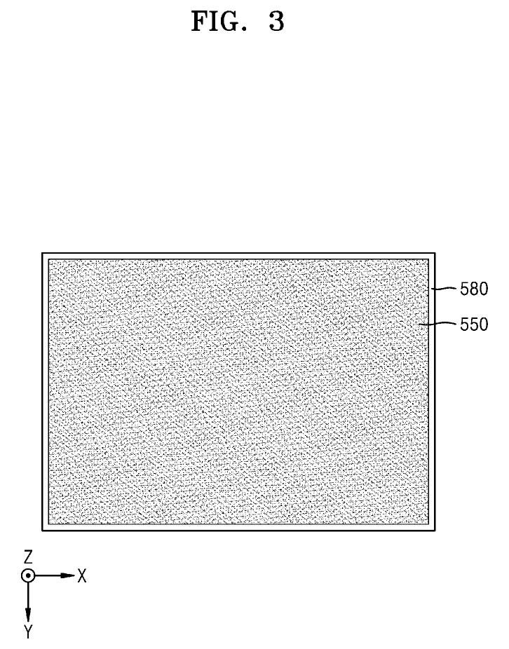

FIG. 2 is a cross-sectional view illustrating a semiconductor package according to an embodiment. FIG. 3 is a plan view taken along line A1-A1’ of FIG. 2 according to an embodiment. Hereinafter, redundant descriptions with reference to FIG. 1 may be omitted, and differences therebetween may be mainly described.

Referring to FIGS. 2 and 3, a semiconductor package 11 may include the first redistribution structure 100, the first semiconductor chip 200, the conductive pillar 280, the molding member 290, the second redistribution structure 300, the second semiconductor chip 400, the first thermally conductive adhesive layer 440, the second thermally conductive adhesive layer 450, the second heat transfer block 500, the third thermally conductive adhesive layer 550, a dam 580, and the heat dissipation member 600.

The first redistribution structure 100 may include the first redistribution insulating layer 110 and the first redistribution pattern 130. The first semiconductor chip 200 and the conductive pillar 280 may be located on the first redistribution structure 100. The molding member 290 may surround the first semiconductor chip 200 and the conductive pillar 280 on the first redistribution structure 100.

The second semiconductor chip 400 may be located on the second redistribution structure 300. According to one or more embodiments, the second semiconductor chip 400 may be mounted on the second redistribution structure 300 in a flip-chip manner through the chip connection bump 410 and the underfill material layer 420 surrounding the chip connection bump 410.

The heat transfer block 500 may be located on the second redistribution structure 300. The heat transfer block 500 may be provided on the second redistribution structure 300 and be spaced apart from the second semiconductor chip 400 in the first horizontal X-axis direction and the vertical Z-axis direction. The heat transfer block 500 may be fixed on the second redistribution structure 300 by the first thermally conductive adhesive layer 440. A lower surface of the heat transfer block 500 may be in contact with the first thermally conductive adhesive layer 440. The heat transfer block 500 may include the body portion 520 and the protrusion portion 510. The body portion 520 may be located to overlap the first semiconductor chip 200 in the vertical Z-axis direction. The protrusion portion 510 may extend from side surfaces of the body portion 520 toward an upper portion of the second semiconductor chip 400 in the first horizontal X-axis direction. An upper surface and a lower surface of the protrusion portion 510 may be flat. The protrusion portion 510 may be fixed to an upper surface of the second semiconductor chip 400 through the second thermally conductive adhesive layer 450. The protrusion portion 510 may include a material resistant to distortion. The protrusion portion 510 may hold the upper surface of the second semiconductor chip 400 through the second thermally conductive adhesive layer 450.

The first thermally conductive adhesive layer 440 may be disposed between a lower surface of the body portion 520 of the heat transfer block 500 and an upper surface of the second redistribution structure 300. The second thermally conductive adhesive layer 450 may be disposed between the lower surface of the protrusion portion 510 of the heat transfer block 500 and the upper surface of the second semiconductor chip 400.

According to one or more embodiments, a thermal conductivity of the first thermally conductive adhesive layer 440 may be greater than a thermal conductivity of the second thermally conductive adhesive layer 450, and an adhesion of the first thermally conductive adhesive layer 440 may be less than an adhesion of the second thermally conductive adhesive layer 450. According to one or more embodiments, a content ratio of a resin constituting the first thermally conductive adhesive layer 440 may be less than a content ratio of a resin constituting the second thermally conductive adhesive layer 450.

According to one or more embodiments, the dam 580 may be located on an upper surface of the heat transfer block 500. The dam 580 may have a rectangular or square ring shape in a plan view, the dam 580 protruding upward in the vertical Z-axis direction from one or more edges of the heat transfer block 500. As used in the disclosure, “rectangular” shapes may also encompass “square” shapes. The dam 580 may surround the third thermally conductive adhesive layer 550.

In one or more embodiments, the dam 580 may include an adhesive material. The dam 580 may be formed by applying an adhesive material to the upper surface of the heat transfer block 500 to surround the third thermally conductive adhesive layer 550. According to embodiments, the dam 580 may be a film having its own adhesive properties. According to embodiments, the dam 580 may include a material such as epoxy, silicon, polyimide, or acrylic.

In some embodiments, the dam 580 may be integrally formed with the heat transfer block 500. That is, the dam 580 may function as a part of the heat transfer block 500. Accordingly, the dam 580 may include the same material as the heat transfer block 500.

The dam 580 may prevent the third thermally conductive adhesive layer 550 from flowing along the upper surface of the heat transfer block 500 before the third thermally conductive adhesive layer 550 is cured.

The third thermally conductive adhesive layer 550 may be located on the upper surface of the heat transfer block 500. The third thermally conductive adhesive layer 550 may be located between the heat transfer block 500 and the heat dissipation member 600. The third thermally conductive adhesive layer 550 may be evenly deposited or applied on the upper surface of the heat transfer block 500.

The heat dissipation member 600 may be located on an upper surface of the third thermally conductive adhesive layer 550. The heat dissipation member 600 may include a heat slug or a heat sink.

The dam 580 is located on the upper surface of the heat transfer block 500 in the semiconductor package 11 according to the disclosure, thereby preventing the third thermally conductive adhesive layer 550 from flowing along the upper surface of the heat transfer block 500 before the third thermally conductive adhesive layer 550 is cured. Accordingly, an adhesion reliability of the third thermally conductive adhesive layer 550 may be improved, and adhesion reliability between the heat dissipation member 600 and the heat transfer block 500 through the third thermally conductive adhesive layer 550 may be improved.

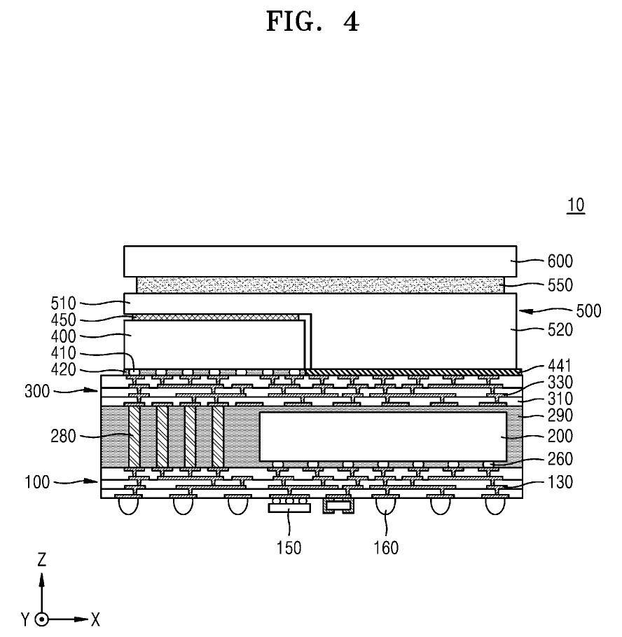

FIG. 4 is a cross-sectional view illustrating a semiconductor package according to an embodiment. Hereinafter, redundant descriptions with reference to FIGS. 1 to 3 may be omitted, and differences therebetween may be mainly described.

Referring to FIG. 4, a semiconductor package 12 may include the first redistribution structure 100, the first semiconductor chip 200, the conductive pillar 280, the molding member 290, the second redistribution structure 300, the second semiconductor chip 400, a first thermally conductive adhesive layer 441, the second thermally conductive adhesive layer 450, the second heat transfer block 500, the third thermally conductive adhesive layer 550, and the heat dissipation member 600.

The first redistribution structure 100 may include the first redistribution insulating layer 110 and the first redistribution pattern 130. The first semiconductor chip 200 and the conductive pillar 280 may be located on the first redistribution structure 100. The molding member 290 may surround the first semiconductor chip 200 and the conductive pillar 280 on the first redistribution structure 100.

The second semiconductor chip 400 may be located on the second redistribution structure 300. According to one or more embodiments, the second semiconductor chip 400 may be mounted on the second redistribution structure 300 in a flip-chip manner through the chip connection bump 410 and the underfill material layer 420 surrounding the chip connection bump 410.

The heat transfer block 500 may be located on the second redistribution structure 300. The heat transfer block 500 may be provided on the second redistribution structure 300 and be spaced apart from the second semiconductor chip 400 in the first horizontal X-axis direction and the vertical Z-axis direction. The heat transfer block 500 may be fixed on the second redistribution structure 300 by the first thermally conductive adhesive layer 441. A lower surface of the heat transfer block 500 may be in contact with the first thermally conductive adhesive layer 441.

The first thermally conductive adhesive layer 441 may be in contact with the underfill material layer 420 in a lateral direction. The first thermally conductive adhesive layer 441 may be cured in contact with the underfill material layer 420 while flowing along an upper surface of the second redistribution structure 300 before being cured. At this time, because the second semiconductor chip 400 is first mounted on the upper surface of the second redistribution structure 300, even though the first thermally conductive adhesive layer 441 flows along the upper surface of the second redistribution structure 300 and contacts the underfill material layer 420 in the lateral direction, no connection failure between the second semiconductor chip 400 and the second redistribution structure 300 may occur.

The heat transfer block 500 may include the body portion 520 and the protrusion portion 510. The body portion 520 may be located to overlap the first semiconductor chip 200 in the vertical Z-axis direction. The protrusion portion 510 may extend from side surfaces of the body portion 520 toward an upper portion of the second semiconductor chip 400 in the first horizontal X-axis direction. An upper surface and a lower surface of the protrusion portion 510 may be flat. The protrusion portion 510 may be fixed to an upper surface of the second semiconductor chip 400 through the second thermally conductive adhesive layer 450. The protrusion portion 510 may include a material resistant to distortion. The protrusion portion 510 may hold the upper surface of the second semiconductor chip 400 through the second thermally conductive adhesive layer 450.

The first thermally conductive adhesive layer 440 may be disposed between a lower surface of the body portion 520 of the heat transfer block 500 and the upper surface of the second redistribution structure 300. The second thermally conductive adhesive layer 450 may be disposed between the lower surface of the protrusion portion 510 of the heat transfer block 500 and the upper surface of the second semiconductor chip 400.

According to one or more embodiments, a thermal conductivity of the first thermally conductive adhesive layer 441 may be greater than a thermal conductivity of the second thermally conductive adhesive layer 450, and an adhesion of the first thermally conductive adhesive layer 441 may be less than an adhesion of the second thermally conductive adhesive layer 450. According to one or more embodiments, a content ratio of a resin constituting the first thermally conductive adhesive layer 441 may be less than a content ratio of a resin constituting the second thermally conductive adhesive layer 450.

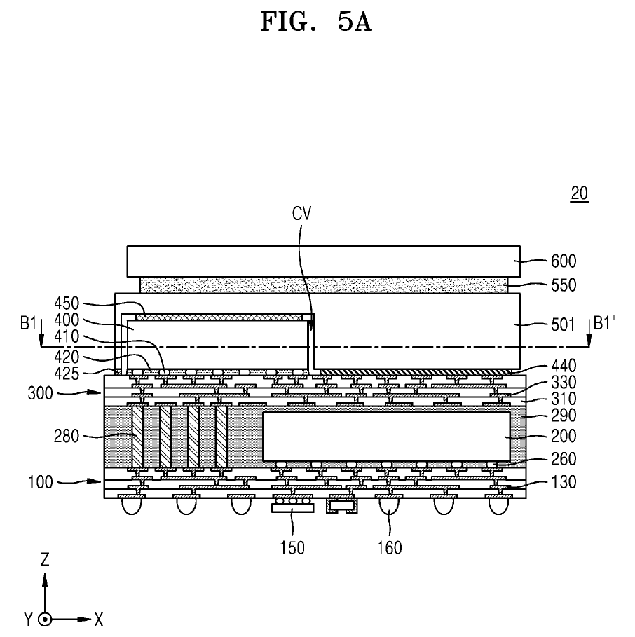

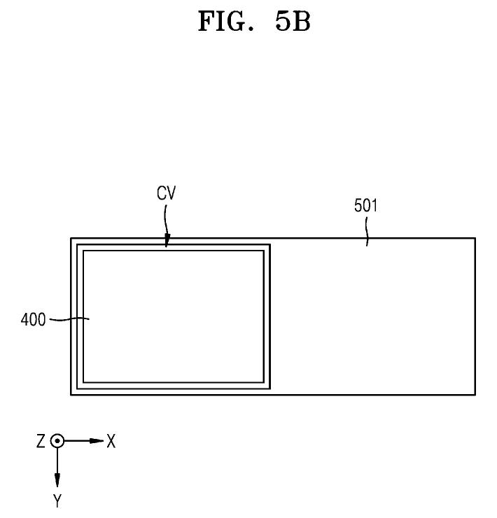

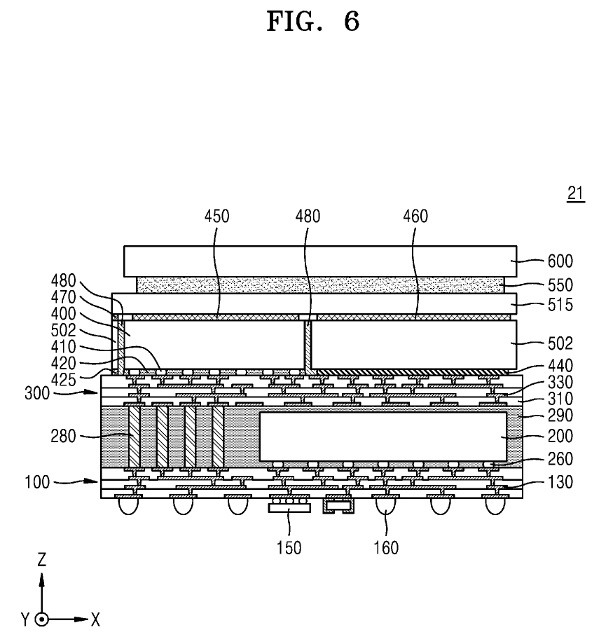

FIG. 5B is a plan view taken along line B1-B1’ of FIG. 5A. FIG. 6 is a cross-sectional view illustrating a semiconductor package according to an embodiment. Hereinafter, redundant descriptions given with reference to FIGS. 1 to 4 may be omitted, and differences therebetween may be mainly described.

Referring to FIGS. 5A and 5B, a semiconductor package 20 may include the first redistribution structure 100, the first semiconductor chip 200, the conductive pillar 280, the molding member 290, the second redistribution structure 300, the second semiconductor chip 400, the first thermally conductive adhesive layer 440, the second thermally conductive adhesive layer 450, a first adhesive member 425, a heat transfer block 501, the third thermally conductive adhesive layer 550, and the heat dissipation member 600.

The first redistribution structure 100 may include the first redistribution insulating layer 110 and the first redistribution pattern 130. The first semiconductor chip 200 and the conductive pillar 280 may be located on the first redistribution structure 100. The molding member 290 may surround the first semiconductor chip 200 and the conductive pillar 280 on the first redistribution structure 100.

The second semiconductor chip 400 may be located on the second redistribution structure 300. According to embodiments, the second semiconductor chip 400 may be mounted on the second redistribution structure 300 in a flip chip manner through the chip connection bump 410 and the underfill material layer 420 surrounding the chip connection bump 410.

The heat transfer block 501 may be located on an upper surface of the second redistribution structure 300. The heat transfer block 501 may be fixed on the second redistribution structure 300 through the first thermally conductive adhesive layer 440 and a first adhesive member 425. The heat transfer block 501 may include a cavity CV. The cavity CV may have a shape extending upward from a lower surface of the heat transfer block 501 in the vertical Z-axis direction. The second semiconductor chip 400 may be located in the cavity CV of the heat transfer block 501. The heat transfer block 501 may surround the second semiconductor chip 400 located in the cavity CV. The second thermally conductive adhesive layer 450 may be located on an upper surface of the second semiconductor chip 400, and the second semiconductor chip 400 may be fixed to the heat transfer block 501 through the second thermally conductive adhesive layer 450.

According to one or more embodiments, a part of a lower surface of the heat transfer block 501 may be in contact with the first adhesive member 425, and the other part of the lower surface of the heat transfer block 501 may be in contact with the first thermally conductive adhesive layer 440. In addition, in one or more embodiments, a part of the lower surface of the heat transfer block 501 may not be in contact with each of the first adhesive member 425 and the first thermally conductive adhesive layer 440, and the part of the heat transfer block 501 that is not in contact with each of the first adhesive member 425 and the first thermally conductive adhesive layer 440 may be spaced apart from the second redistribution structure 300 by a certain distance in the vertical Z-axis direction. According to one or more embodiments, the first adhesive member 425 may be a film having its own adhesive properties. According to one or more embodiments, the first adhesive member 425 may include a material such as epoxy, silicon, polyimide, or acrylic.

The third thermally conductive adhesive layer 550 may be located on an upper surface of the heat transfer block 500. The third thermally conductive adhesive layer 550 may be located between the heat transfer block 500 and the heat dissipation member 600. The third thermally conductive adhesive layer 550 may be evenly located on the upper surface of the heat transfer block 500. The heat dissipation member 600 may be located on an upper surface of the third thermally conductive adhesive layer 550. The heat dissipation member 600 may include a heat slug or a heat sink.

In the semiconductor package 20 according to one or more embodiments of the disclosure, the second semiconductor chip 400 may be fixed to the heat transfer block 501 by the second thermally conductive adhesive layer 450, thereby preventing the second semiconductor chip 400 from being distorted even though heat is generated during the manufacturing process of the semiconductor package 20. In addition, the heat transfer block 501 may have a shape that surrounds the second semiconductor chip 400 compared to FIG. 1, which may reduce the difference in the thermal expansion coefficient between the left and right sides of the semiconductor package 20 with respect to the center of the second redistribution structure 300.

Furthermore, the heat transfer block 501 may be fixed on the second redistribution structure 300 by the first adhesive member 425 and the first thermally conductive adhesive layer 440, and thus the structural stability of the heat transfer block 501 may also be improved.

FIG. 6 is a cross-sectional view illustrating a semiconductor package according to an embodiment. Hereinafter, redundant descriptions given with reference to FIGS. 1-4 and 5A-5B may be omitted, and differences therebetween may be mainly described.

Referring to FIG. 6, a semiconductor package 21 may include the first redistribution structure 100, the first semiconductor chip 200, the conductive pillar 280, the molding member 290, the second redistribution structure 300, the second semiconductor chip 400, the first thermally conductive adhesive layer 440, the second thermally conductive adhesive layer 450, a fourth thermally conductive adhesive layer 460, the first adhesive member 425, a second adhesive member 470, a gap-fill adhesive member 480, a heat transfer block 502, the third thermally conductive adhesive layer 550, and the heat dissipation member 600.

The first redistribution structure 100 may include the first redistribution insulating layer 110 and the first redistribution pattern 130. The first semiconductor chip 200 and the conductive pillar 280 may be located on the first redistribution structure 100. The molding member 290 may surround the first semiconductor chip 200 and the conductive pillar 280 on the first redistribution structure 100.

The second semiconductor chip 400 may be located on the second redistribution structure 300. According to one or more embodiments, the second semiconductor chip 400 may be mounted on the second redistribution structure 300 in a flip-chip manner through the chip connection bump 410 and the underfill material layer 420 surrounding the chip connection bump 410.

The heat transfer block 502 may be located on an upper surface of the second redistribution structure 300. The heat transfer block 502 may be fixed on the second redistribution structure 300 through the first thermally conductive adhesive layer 440 and the first adhesive member 425. The heat transfer block 502 may be located on the second redistribution structure 300 to surround the second semiconductor chip 400. The heat transfer block 502 may include a hole penetrating from a lower surface to an upper surface of the heat transfer block 502 in the vertical Z-axis direction. The second semiconductor chip 400 may be provided in the hole.

According to one or more embodiments, unlike the heat transfer blocks 500 and 501 described with reference to FIGS. 1-4 and 5A-5B, the heat transfer block 502 may not overlap the second semiconductor chip 400 in the vertical Z-axis direction. In one or more embodiments, the upper surface of the heat transfer block 502 and an upper surface of the second semiconductor chip 400 may be at the same vertical level.

A space between the heat transfer block 502 and the second semiconductor chip 400 may be filled with the gap-fill adhesive member 480. The gap-fill adhesive member 480 may fill the space between the second semiconductor chip 400 and the heat transfer block 502.

The second thermally conductive adhesive layer 450 may be located on the upper surface of the second semiconductor chip 400, and the fourth thermally conductive adhesive layer 460 and the second adhesive member 470 may be located on the upper surface of the heat transfer block 502. The fourth thermally conductive adhesive layer 460 may overlap the first thermally conductive adhesive layer 440 in the vertical Z-axis direction, and the second adhesive member 470 may overlap the first adhesive member 425 in the vertical Z-axis direction.

A thermal conductive plate 515 may be located on the second semiconductor chip 400 and the heat transfer block 502. The thermal conductive plate 515 may be fixed on the second semiconductor chip 400 and the heat transfer block 502 through the second thermally conductive adhesive layer 450, the fourth thermally conductive adhesive layer 460, and the second adhesive member 470. According to one or more embodiments, the thermal conductive plate 515 may include substantially the same material as the heat transfer block 502, and may function in a manner similar to the protrusion portion 510.

The third thermally conductive adhesive layer 550 may be located on an upper surface of the thermal conductive plate 515, and the heat dissipation member 600 may be fixed on the thermal conductive plate 515 through the third thermally conductive adhesive layer 550.

In the semiconductor package 21 according to one or more embodiments of the disclosure, the second semiconductor chip 400 may be fixed to the heat transfer block 502 through the gap-fill adhesive member 480. In addition, the second semiconductor chip 400 may be fixed to the thermal conductive plate 515 through the second thermally conductive adhesive layer 450. Accordingly, even though heat is applied during the manufacturing process of the semiconductor package 21, the second semiconductor chip 400 may be fixed by the thermal conductive plate 515 and the heat transfer block 502, and thus distortion of the second semiconductor chip 400 may be prevented. Accordingly, the third thermally conductive adhesive layer 550 may not be ultimately separated from the heat dissipation member 600 and the thermal conductive plate 515.

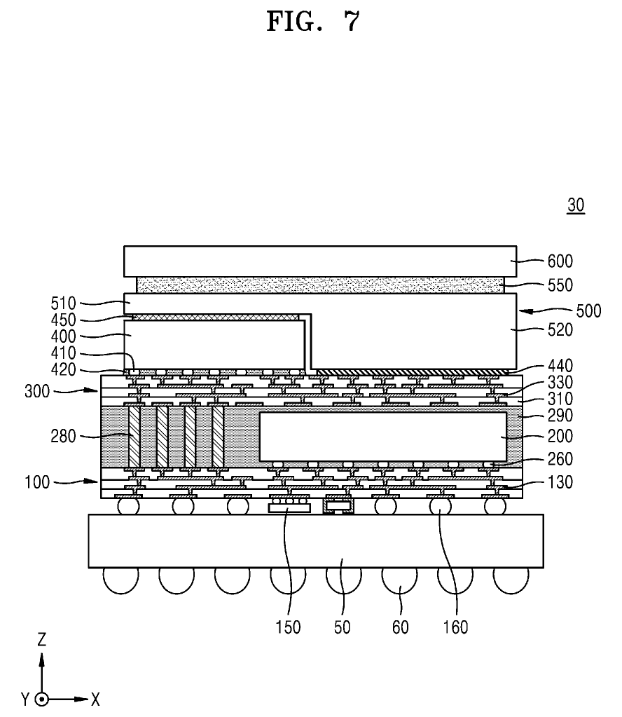

FIG. 7 is a cross-sectional view illustrating a semiconductor package according to an embodiment. Hereinafter, redundant descriptions given with reference to FIGS. 1, 2, 3, 4, 5A, 5B, and 6, may be omitted, and differences therebetween may be mainly described.

Referring to FIG. 7, a semiconductor package 30 may include a first substrate 50, the first redistribution structure 100, the first semiconductor chip 200, the conductive pillar 280, the molding member 290, the second redistribution structure 300, the second semiconductor chip 400, the first thermally conductive adhesive layer 440, the second thermally conductive adhesive layer 450, the second heat transfer block 500, the third thermally conductive adhesive layer 550, and the heat dissipation member 600.

The first substrate 50, which may be a substrate on which the first redistribution structure 100 is mounted, may be understood as a package substrate. According to embodiments, the first substrate 50 may be formed based on a ceramic substrate, a printed circuit board (PCB), an organic substrate, etc.

An external connection terminal 60 may be located on a lower surface of the first substrate 50. The external connection terminal 60 may be electrically connected to an external device, for example, a motherboard. The first redistribution structure 100 may be electrically connected to the external device through the external connection terminal 60.

The external connection terminal 60 may include a solder ball. However, according to one or more an embodiment, the external connection terminal 60 may have a structure including a pillar and a solder. The external connection terminal 60 may include at least one of copper (Cu), silver (Ag), gold (Au), or tin (Sb).

The first redistribution structure 100 may include the first redistribution insulating layer 110 and the first redistribution pattern 130. The first semiconductor chip 200 and the conductive pillar 280 may be located on the first redistribution structure 100. The molding member 290 may surround the first semiconductor chip 200 and the conductive pillar 280 on the first redistribution structure 100.

The second semiconductor chip 400 may be located on the second redistribution structure 300. According to embodiments, the second semiconductor chip 400 may be mounted on the second redistribution structure 300 in a flip-chip manner through the chip connection bump 410 and the underfill material layer 420 may surround the chip connection bump 410.

The heat transfer block 500 may be located on the second redistribution structure 300. The heat transfer block 500 may be provided on the second redistribution structure 300 and be spaced apart from the second semiconductor chip 400 in the first horizontal X-axis direction and the vertical Z-axis direction. The heat transfer block 500 may be fixed on the second redistribution structure 300 by the first thermally conductive adhesive layer 440. A lower surface of the heat transfer block 500 may be in contact with the first thermally conductive adhesive layer 440. The heat transfer block 500 may include the body portion 520 and the protrusion portion 510. The body portion 520 may be located to overlap the first semiconductor chip 200 in the vertical Z-axis direction. The protrusion portion 510 may extend from side surfaces of the body portion 520 toward an upper portion of the second semiconductor chip 400 in the first horizontal X-axis direction. An upper surface and a lower surface of the protrusion portion 510 may be flat. The protrusion portion 510 may be fixed to an upper surface of the second semiconductor chip 400 through the second thermally conductive adhesive layer 450. The protrusion portion 510 may include a material resistant to distortion. The protrusion portion 510 may hold the upper surface of the second semiconductor chip 400 through the second thermally conductive adhesive layer 450.

The first thermally conductive adhesive layer 440 may be disposed between a lower surface of the body portion 520 of the heat transfer block 500 and an upper surface of the second redistribution structure 300. The second thermally conductive adhesive layer 450 may be disposed between the lower surface of the protrusion portion 510 of the heat transfer block 500 and the upper surface of the second semiconductor chip 400.

According to one or more embodiments, a thermal conductivity of the first thermally conductive adhesive layer 440 may be greater than a thermal conductivity of the second thermally conductive adhesive layer 450, and an adhesion of the first thermally conductive adhesive layer 440 may be less than an adhesion of the second thermally conductive adhesive layer 450. According to one or more embodiments, a content ratio of a resin constituting the first thermally conductive adhesive layer 440 may be less than a content ratio of a resin constituting the second thermally conductive adhesive layer 450.

The third thermally conductive adhesive layer 550 may be located on an upper surface of the heat transfer block 500. The third thermally conductive adhesive layer 550 may be located between the heat transfer block 500 and the heat dissipation member 600. The third thermally conductive adhesive layer 550 may be evenly deposited or applied on the upper surface of the heat transfer block 500.

The heat dissipation member 600 may be located on an upper surface of the third thermally conductive adhesive layer 550. The heat dissipation member 600 may include a heat slug or a heat sink.

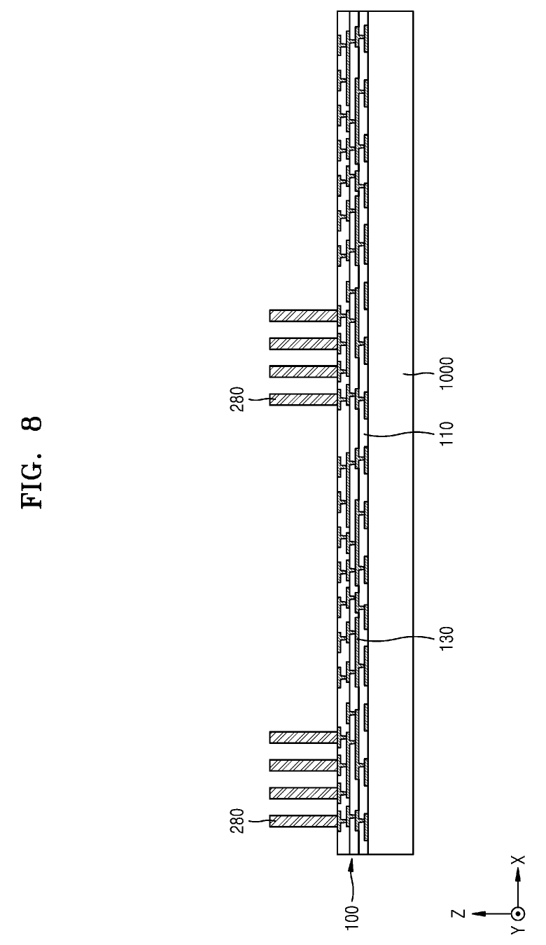

FIGS. 8 to 18 are cross-sectional views illustrating a method of manufacturing a semiconductor package. Hereinafter, redundant descriptions given with reference to FIGS. 1, 2, 3, 4, 5A, 5B, 6, and 7, may be omitted, and differences therebetween may be mainly described.

Referring to FIG. 8, the first redistribution structure 100 may be formed on a first carrier substrate 1000, and the conductive pillars 280 may be formed on the first redistribution structure 100.

The first redistribution structure 100 may include the first redistribution insulating layer 110 and the first redistribution pattern 130. Each of the conductive pillars 280 may have a shape extending in the vertical Z-axis direction and be electrically connected to the first redistribution pattern 130.

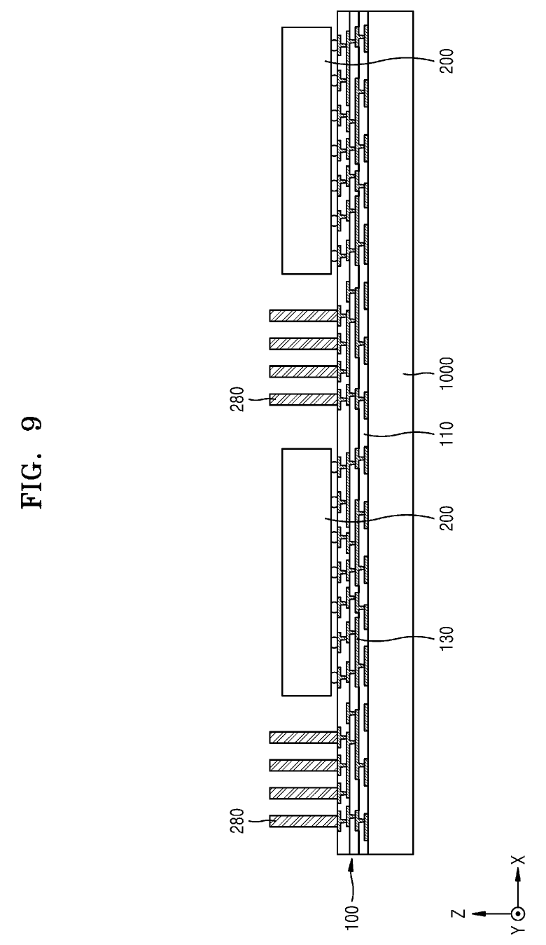

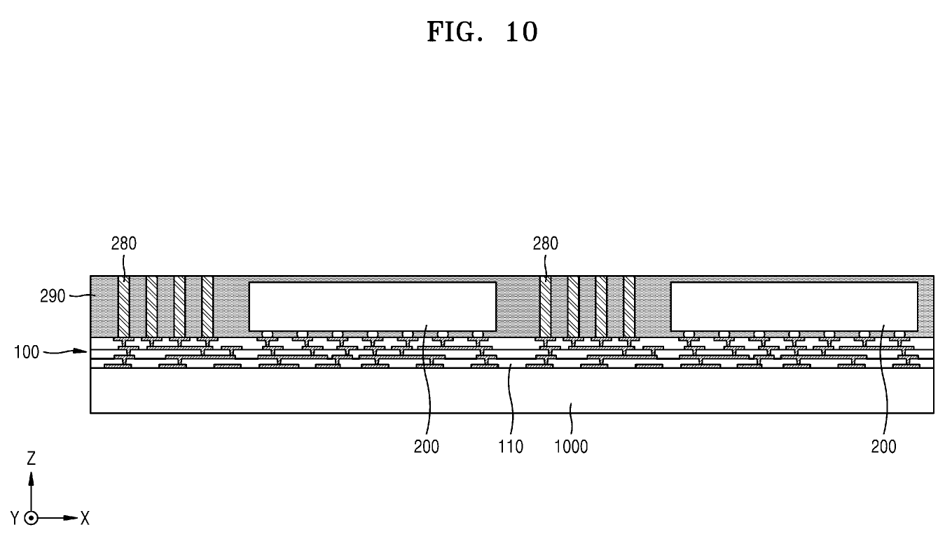

Referring to FIGS. 9 and 10, the first semiconductor chips 200 may be mounted on the first redistribution structure 100, and the molding member 290 covering the first semiconductor chips 200 and the conductive pillars 280 may be formed. The molding member 290 may be initially formed to cover an upper surface of each of the first semiconductor chips 200 and the conductive pillars 280, and then polished until the upper surface of each of the conductive pillars 280 is exposed above in the vertical Z-axis direction through a chemical mechanical polishing (CMP) process. An upper surface of the molding member 290 may be coplanar with the upper surface of each of the conductive pillars 280.

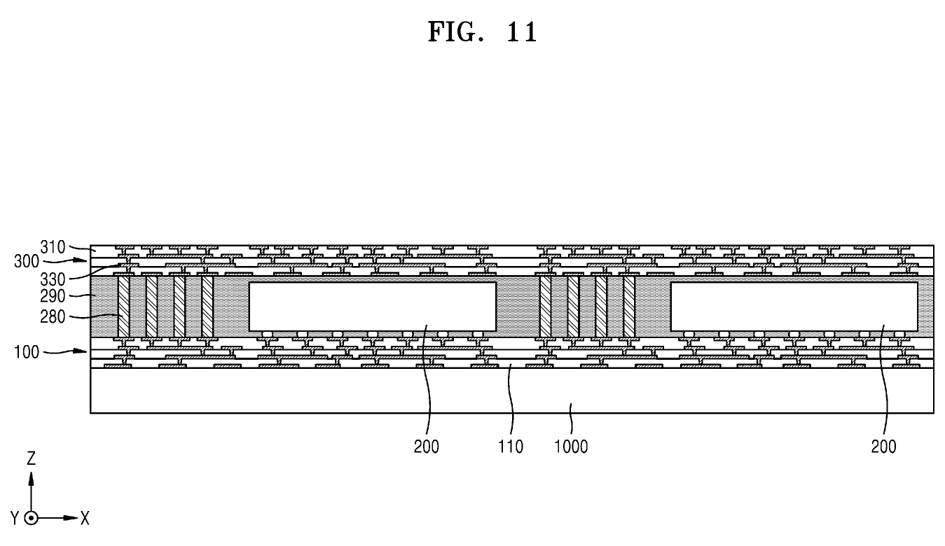

Referring to FIG. 11, the second redistribution structure 300 may be formed on the upper surface of the molding member 290. The second redistribution structure 300 may include the second redistribution pattern 330 and the second redistribution insulating layer 310. The second redistribution structure 300 may be electrically connected to each of the conductive pillars 280.

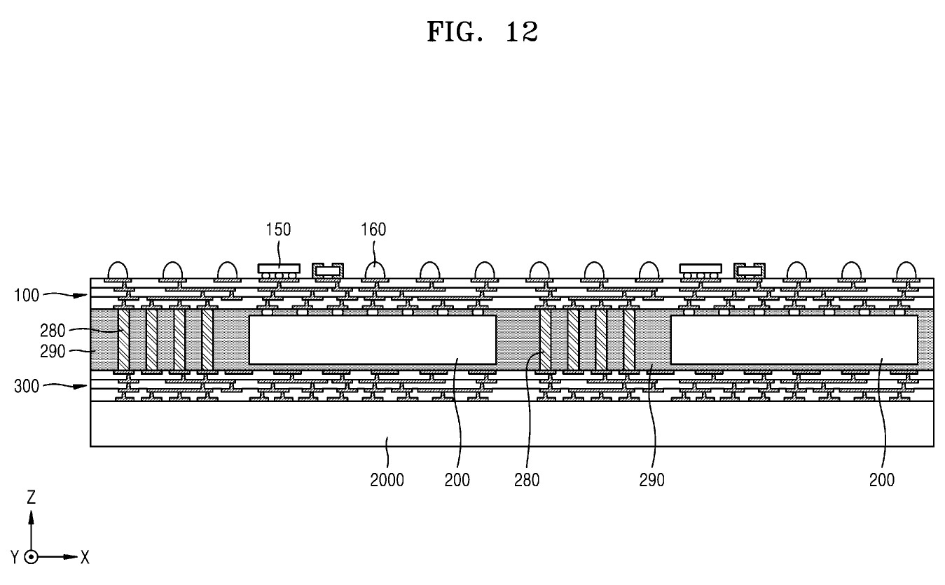

Referring to FIG. 12, the first carrier substrate 1000 (see FIG. 11) may be removed, the structure of FIG. 11 may be turned over in the vertical Z-axis direction, and then a second carrier substrate 2000 may be attached to a surface of the second redistribution structure 300 in a +Z direction. Thereafter, the substrate connection bump 160 and the passive element component 150 may be formed on a surface of the first redistribution structure 100 in a -Z direction.

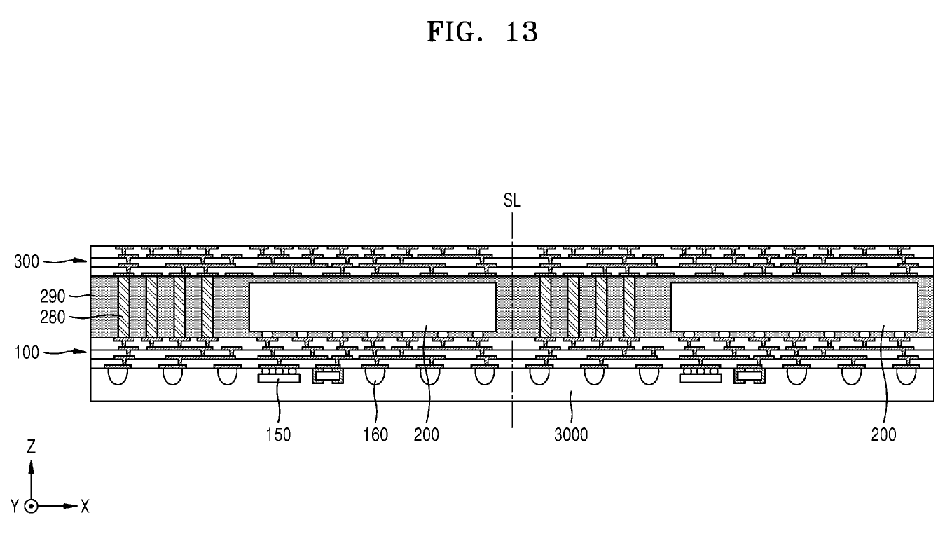

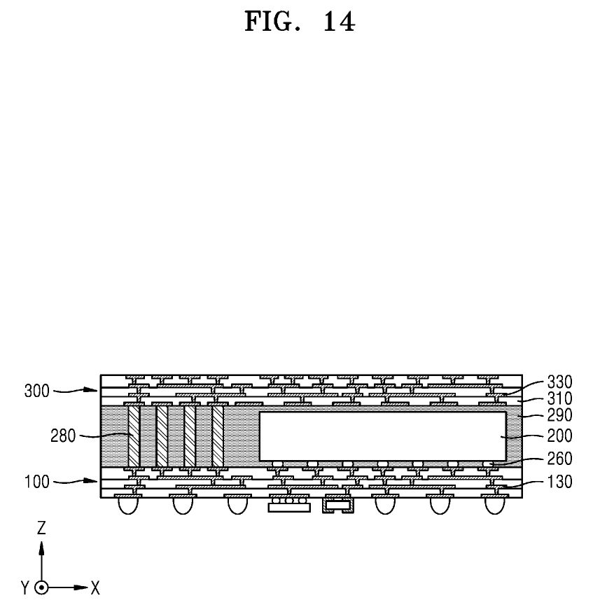

Referring to FIGS. 13 and 14, the second carrier substrate 2000 (FIG. 12) may be removed, the structure of FIG. 12 may be turned over in the vertical Z-axis direction, and then a saw tape may be attached to a lower surface of the first redistribution structure 100. Thereafter, the structure of FIG. 13 may be cut into an individual structure as shown in FIG. 14 along a scribe lane SL.

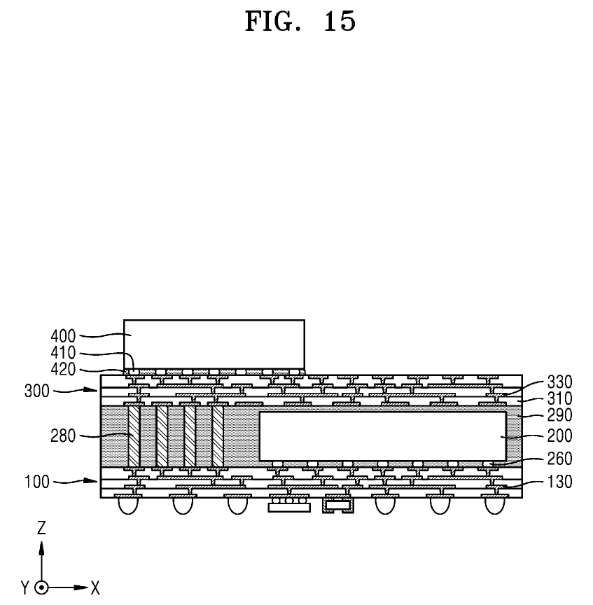

Referring to FIG. 15, the second semiconductor chip 400 may be mounted on the second redistribution structure 300 of the structure of FIG. 14 and may be cut into an individual structure. The second semiconductor chip 400 may be mounted on the second redistribution structure 300 in a flip-chip manner through the chip connection bump 410 such as a microbump. The underfill material layer 420 surrounding the chip connection bump 410 may be located between the second semiconductor chip 400 and the second redistribution structure 300.

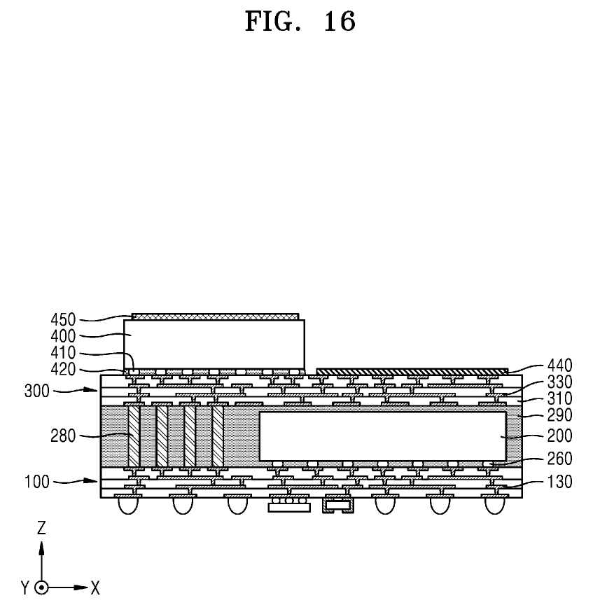

Referring to FIG. 16, the first thermally conductive adhesive layer 440 may be applied to a part of an upper surface of the second redistribution structure 300, and the second thermally conductive adhesive layer 450 may be applied to an upper surface of the second semiconductor chip 400. The first thermally conductive adhesive layer 440 may flow along the upper surface of the second redistribution structure 300 before being cured. However, the underfill material layer 420 may cover an upper pad of the second redistribution structure 300 connected to the second semiconductor chip 400, and thus an electrical connection failure between the second semiconductor chip 400 and the second redistribution structure 300, caused by the flow of the first thermally conductive adhesive layer 440, may be prevented.

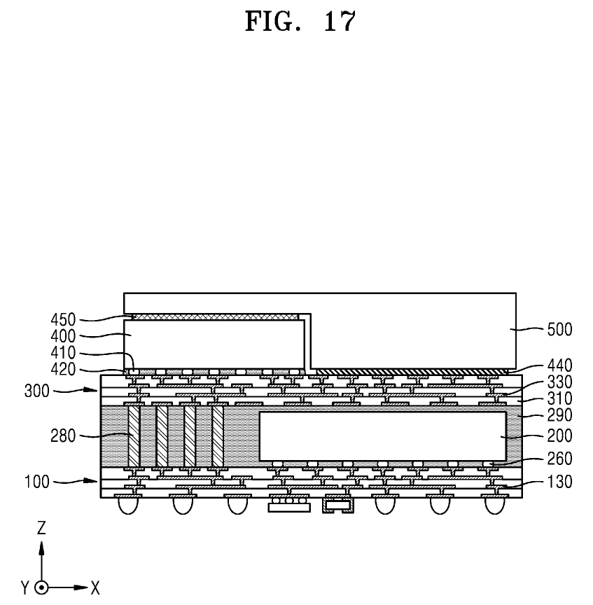

Referring to FIG. 17, the heat transfer block 500 may be mounted on the second redistribution structure 300 and the second semiconductor chip 400. The heat transfer block 500 may be fixed on the upper surface of the second redistribution structure 300 through the first thermally conductive adhesive layer 440, and may be fixed on the upper surface of the second semiconductor chip 400 through the second thermally conductive adhesive layer 450.

The heat transfer block 500 may fix the second semiconductor chip 400 through the second thermally conductive adhesive layer 450 to prevent distortion of the second semiconductor chip 400.

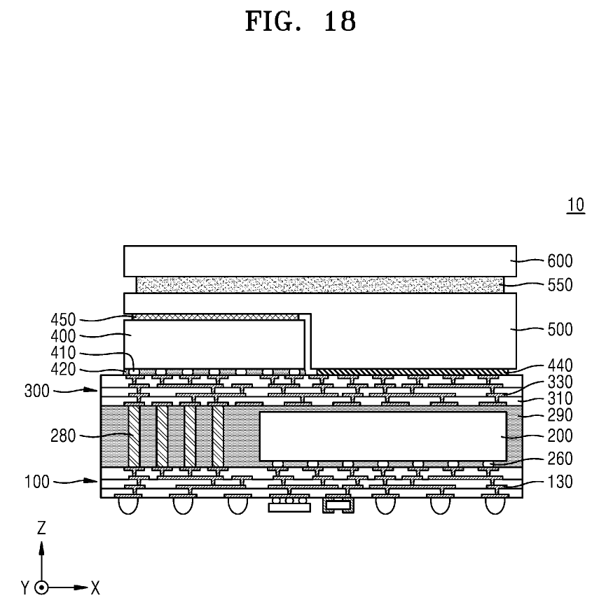

Referring to FIG. 18, the semiconductor package 10 may be completely manufactured by applying the third thermally conductive adhesive layer 550 to an upper surface of the heat transfer block 500 and attaching the heat dissipation member 600 on the third thermally conductive adhesive layer 550.

While example embodiments of the disclosure has been particularly shown and described, it will be understood that various changes in form and details may be made therein without departing from the spirit and scope of the following claims.

What is claimed is:

1. A semiconductor package comprising:
a first redistribution structure;
a first semiconductor chip on the first redistribution structure;
at least one conductive pillar on the first redistribution structure and spaced apart from the first semiconductor chip in a horizontal direction;
a molding member on the first redistribution structure and around the first semiconductor chip and the at least one conductive pillar;
a second redistribution structure on the molding member;
a second semiconductor chip on the second redistribution structure;
a first thermally conductive adhesive layer on the second redistribution structure;
a second thermally conductive adhesive layer on an upper surface of the second semiconductor chip; and
a heat transfer block on the second redistribution structure, the heat transfer block comprising:
a protrusion portion in contact with the second thermally conductive adhesive layer, and
a body portion in contact with the first thermally conductive adhesive layer.

2. The semiconductor package of claim 1, further comprising:
a dam extending in a vertical direction on an upper surface of the heat transfer block and having a rectangular ring shape in a plan view.

3. The semiconductor package of claim 1, further comprising:
a chip connection bump between the second semiconductor chip and the second redistribution structure, and
an underfill material layer around the chip connection bump,
wherein the first thermally conductive adhesive layer is in contact with the underfill material layer in a lateral direction.

4. The semiconductor package of claim 1, wherein the heat transfer block surrounds the upper surface and side surfaces of the second semiconductor chip.

5. The semiconductor package of claim 1, wherein the protrusion portion comprises a thermal conductive plate,
wherein the body portion is around side surfaces of the second semiconductor chip and does not overlap the second semiconductor chip in a plan view, and
wherein the semiconductor package further comprises:
a fourth thermally conductive adhesive layer fixing the thermal conductive plate and the body portion to each other; and
a gap-fill adhesive member is between the second semiconductor chip and the body portion.

6. The semiconductor package of claim 5, wherein at least two side surfaces of the second semiconductor chip are in contact with the gap-fill adhesive member, and
wherein the upper surface of the second semiconductor chip is in contact with the second thermally conductive adhesive layer.

7. The semiconductor package of claim 1, wherein a thermal conductivity of the first thermally conductive adhesive layer is greater than a thermal conductivity of the second thermally conductive adhesive layer, and
wherein an adhesion of the second thermally conductive adhesive layer is greater than an adhesion of the first thermally conductive adhesive layer.

8. The semiconductor package of claim 7, wherein each of the first thermally conductive adhesive layer and the second thermally conductive adhesive layer comprises a resin and a filler,
wherein the resin of the first thermally conductive adhesive layer comprises silicone and the filler of the first thermally conductive adhesive layer comprises aluminum, and
wherein the resin of the second thermally conductive adhesive layer comprises epoxy and the filler of the second thermally conductive adhesive layer comprises silver.

9. The semiconductor package of claim 1, wherein a center of the first semiconductor chip is spaced apart from a center of the first redistribution structure in the horizontal direction, and
wherein of the at least one conductive pillar is on only one side surface of the first semiconductor chip.

10. The semiconductor package of claim 1, wherein a thickness of the first thermally conductive adhesive layer in a vertical direction is within a range of about 45 μm to about 55 μm, and
wherein a thickness of the second thermally conductive adhesive layer in the vertical direction is within a range of about 50 μm to about 100 μm.

11. A semiconductor package comprising:
a first redistribution structure;
a first semiconductor chip on the first redistribution structure;
a conductive pillar on the first redistribution structure and spaced apart from the first semiconductor chip in a horizontal direction;
a molding member on the first redistribution structure and around the first semiconductor chip and the conductive pillar;
a second redistribution structure on the molding member;
a second semiconductor chip on the second redistribution structure;
a first thermally conductive adhesive layer on the second redistribution structure;
a second thermally conductive adhesive layer on an upper surface of the second semiconductor chip;
a heat transfer block on the second redistribution structure, the heat transfer block comprising:
a protrusion portion in contact with an upper surface of the second thermally conductive adhesive layer, and
a body portion in contact with an upper surface of the first thermally conductive adhesive layer, and spaced apart from the second semiconductor chip in the horizontal direction;
a third thermally conductive adhesive layer on an upper surface of the heat transfer block; and
a heat dissipation member on the third thermally conductive adhesive layer.

12. The semiconductor package of claim 11, further comprising:
a dam extending in a vertical direction on the upper surface of the heat transfer block and around the third thermally conductive adhesive layer.

13. The semiconductor package of claim 12, wherein the dam comprises a film having adhesive properties.

14. The semiconductor package of claim 12, wherein the dam is integral with the heat transfer block and comprises a same material as the heat transfer block.

15. The semiconductor package of claim 11, wherein the heat transfer block comprises a cavity extending in a vertical direction from a lower surface of the heat transfer block,
wherein the second semiconductor chip is in the cavity, and
wherein the heat transfer block is around side surfaces and the upper surface of the second semiconductor chip.

16. The semiconductor package of claim 11, wherein a thermal conductivity of the first thermally conductive adhesive layer is greater than a thermal conductivity of the second thermally conductive adhesive layer, and
wherein an adhesion of the second thermally conductive adhesive layer is greater than an adhesion of the first thermally conductive adhesive layer.

17. The semiconductor package of claim 11, wherein the protrusion portion comprises a thermal conductive plate,
wherein the body portion surrounds side surfaces of the second semiconductor chip and does not overlap the second semiconductor chip in a plan view, and
wherein the semiconductor package further comprises:
a fourth thermally conductive adhesive layer fixing the thermal conductive plate and the body portion to each other; and
a gap-fill adhesive member is between the second semiconductor chip and the body portion.

18. A semiconductor package comprising:
a package substrate;
a first redistribution structure comprising a first redistribution pattern and a first redistribution insulating layer on the package substrate;
a first semiconductor chip on the first redistribution structure and having a center spaced apart from a center of the first redistribution structure in a horizontal direction;
a plurality of conductive pillars on the first redistribution structure and spaced apart from the first semiconductor chip in the horizontal direction;
a molding member on the first redistribution structure and around the first semiconductor chip and the plurality of conductive pillars;
a second redistribution structure on the molding member and comprising a second redistribution pattern and a second redistribution insulating layer;
a second semiconductor chip on the second redistribution structure and overlapping at least one of the plurality of conductive pillars in a vertical direction;
a first thermally conductive adhesive layer on the second redistribution structure;
a second thermally conductive adhesive layer on an upper surface of the second semiconductor chip;
a heat transfer block on the second redistribution structure, in contact with an upper surface of the second thermally conductive adhesive layer and an upper surface of the first thermally conductive adhesive layer, and spaced apart from the second semiconductor chip in the horizontal direction;
a third thermally conductive adhesive layer on an upper surface of the heat transfer block; and
a heat dissipation member on the third thermally conductive adhesive layer,
wherein a thermal conductivity of the first thermally conductive adhesive layer is greater than a thermal conductivity of the second thermally conductive adhesive layer,
wherein an adhesion of the second thermally conductive adhesive layer is greater than an adhesion of the first thermally conductive adhesive layer,
wherein the third thermally conductive adhesive layer comprises a sheet type,
wherein a thickness of the first thermally conductive adhesive layer in the vertical direction is within a range of about 45 μm to about 55 μm, and
wherein a thickness of the second thermally conductive adhesive layer in the vertical direction is within a range of about 50 μm to about 100 μm.

19. The semiconductor package of claim 18, wherein the heat transfer block comprises a cavity extending in the vertical direction from a lower surface of the heat transfer block,
wherein the second semiconductor chip is in the cavity, and
wherein the heat transfer block is around side surfaces and the upper surface of the second semiconductor chip.

20. The semiconductor package of claim 18, wherein each of the first thermally conductive adhesive layer and the second thermally conductive adhesive layer comprises a resin and a filler,
wherein the resin of the first thermally conductive adhesive layer comprises silicone and the filler of the first thermally conductive adhesive layer comprises aluminum, and
wherein the resin of the second thermally conductive adhesive layer comprises epoxy and the filler of the second thermally conductive adhesive layer comprises silver.
